(19) United States
(12) Patent Application Publication
(10) Pub. No.: US 2010/0136224 A1
(43) Pub. Date: Jun. 3, 2010

(54) STABLE NANOTUBE COATINGS

(76) Inventors: David Alexander Britz, Cambridge, MA (US); David H. Landis, JR., Barrington, RI (US); Paul J. Glatkowski, Littletown, MA (US)

Correspondence Address: NOVAK DRUCE + QUIGG LLP, 1300 EYE STREET NW, SUITE 1000 WEST TOWER, WASHINGTON, DC, 20005, US

(21) Appl. No.: 11/685,724

(22) Filed: Mar. 13, 2007

Related U.S. Application Data
(63) Continuation-in-part of application No. 11/682,303, filed on Mar. 5, 2007.
(60) Provisional application No. 60/781,381, filed on Mar. 13, 2006.

(51) Int. Cl. D01F 9/12; B05D 5/12; H01B 1/04; C23C 14/28

(52) U.S. Cl. 427/122; 423/447.2; 252/502; 252/510; 252/511; 252/506; 427/595; 977/742; 977/932

(57) ABSTRACT

The present invention relates to purified transparent carbon nanotube (CNT) conductive layers or coatings that comprise at least one additional material to form a composite. Adding a material to the CNT layer or coating improves conductivity, transparency, and/or the performance of a device comprising a transparent conductive CNT layers or coating This composite may be used in photovoltaic devices, OLEDs, LCD displays, or touch screens.

### REFERENCE TO RELATED APPLICATIONS

This application claims priority to United States Provisional Application No. 60/781,381 entitled “Additives for Stabile Nanotube Coatings” filed Mar. 13, 2006 and is a continuation in part of U.S. application Ser. No. 11/682,303, filed Mar. 5, 2007. The entirety of both of these applications is specifically and entirely incorporated by reference.

### BACKGROUND

1. Field of the Invention

The present invention relates to purified transparent carbon nanotube (CNT) conductive layers or coatings that comprise at least one additional material to form a composite. Adding a material to the CNT layer or coating improves conductivity, transparency, and/or the performance of a device comprising a transparent conductive CNT layers or coating. This composite may be used in photovoltaic devices, OLEDs, LCD displays, or touch screens.

2. Description of Related Art

Martin et al. (US Patent Application 20030179986 and US Patent No. 7033672) disclose transparent antistatic windows for micro-opto-electro-mechanical lenses, They describe a composite comprising single-walled carbon nanotubes (“SWNTs”) and fluoroploymers. They also disclose the use of ionomer films for antistatic windows, including the use of Nafion® (“Nafion”).

Bradley et al. (U.S. Pat. No. 6,894,359) describe nanotube transistors coated with polymers to inhibit sensor sensitivity. Other disclosures by the same group (Star et al., Electroanalysis, 2004, 16, 1-2) describe field effect devices with dimensions of less than 100 microns. Further, the authors describe Nafion as enhancing sensitivity of the electronic properties of the device to environmental humidity, which teaches against the claims of U.S. Pat. No. 6,894,359. The conductivity of the nanotube network described by Star et al. is one order of magnitude more conductive than Nafion. Nation has a volume conductivity of about 110 mS/cm to about 0.01 mS/cm. The nanotube networks of Star et al. and Bradley et al. are about 1,000 mS/cm to 0.1 mS/cm or 1 S/cm at most.

Masel et al. (U.S. Pat. No. 7,108,773) disclose an ink comprising carbon nanotubes, Nafion, and platinum-palladium catalyst. The inventors use these inks exclusively for the catalyst layer in fuel cells. Further, the inventors disclose the nanotube weight ratio of 1% in the ink. The inventors do not disclose the stability of their inks, nor do they disclose any changes in ink viscosity. Therefore it is impossible to know how to make such inks stable and uniform, which are both requirements for high conductivity and uniform optical appearance in films.

Chen et al. (US. Patent Application 20030077515) describe methods of making electrically conductive nanotube compositions, wherein a monomer is polymerized with carbon nanotubes in an ink. Ionic polymers are disclosed as a polymer fowled from a monomer.

### SUMMARY OF THE INVENTION

The present invention overcomes the problems and disadvantages associated with current strategies and designs and provides new materials and methods for improving the conductivity, transparency, mechanical adhesion, abrasion resistance, coating uniformity, and stability under radiation and under extreme temperatures of carbon nanotube-containing compositions. The present invention also provides new materials and methods for purifying carbon nanotube-containing compositions to contain essentially no detectable metals.

One embodiment of the present invention is directed to a method of forming a stable transparent conductive coating comprising purifying the carbon nanotubes so that they contain no detectable metals, forming a layer of carbon nanotubes, and adding one or more binders in a second coating step.

Another embodiment is directed to the method in which a binder utilized in embodiments of this invention is in a solvent. In another embodiment, the solvent in which the binder is present when added to a CNT composition is removed.

Another embodiment is directed to a method wherein a CNT-containing coating has stable electronic properties and optical properties when exposed to environmental conditions. In another embodiment, the electronic properties comprise surface resistance, and said surface resistance changes less than 100%, less than 90%, less than 80%, less than 70%, less than 60%, less than 50%, less than 40%. less than 30%, less than 20%, less than 10%, less than 5%, or less than 1%, upon exposure to the environmental conditions. Another embodiment is directed to a method as described in embodiments of this invention wherein the environmental conditions include temperatures ranging from 20 to 200 degrees Celsius for periods of time ranging from 1 hour to 5 years. In other embodiments, the environmental conditions include humid condition wherein relative humidity ranges from 10-100%. In other embodiments, the environmental conditions include UVA radiation, or UVB radiation, or UN light ranging from 280nm to 400 nm.

Another embodiment is directed to a method of forming a thin transparent and conductive thin coating comprising depositing a first layer of carbon nanotubes on a substrate, adding a solvent containing binder to the first layer with the solvent containing binder to form a composite wherein the ratio of the carbon nanotubes to the binder is greater than 10% weight, greater than 50% by weight, or greater than 90% by weight.

Other embodiments are directed to method for forming CNT-containing coatings that are homogeneous in the X direction, the Y direction, the Z direction, or combinations thereof.

Another embodiment is directed to a method of forming a thin transparent and conductive coating comprising depositing carbon nanotubes blended with a binder in a solution, wherein the ratio of the carbon nanotubes to the binder is greater than 10% by weight, greater than 50% by weight, or greater than 90% by weight.

Another embodiment of this invention is directed to a method for increasing the transparency of a carbon nanotube coating by between 1 and 10% comprising adding a binder or binders to the carbon nanotube coating. In other embodiments, the transparency depends on the nature of the substrate.

Another embodiment of the invention is directed to a transparent and conductive composition comprised of carbon nanotubes, wherein the composition contains no detectable metal. In other embodiments, the detectable metal is selected from the group consisting of Iron, Itrium, Nickel, Cobalt, Mo, and combinations thereof.

Other embodiments are directed to CNT-containing compositions comprising a binder. In embodiments of this invention, the binder is selected from the group consisting of a dopant, nafion, flemion, thionyl chloride, TCNQ, oxygen, water, nitric acid, sulfurinc acid, a polymeric acid, a fluoropolymeric acid, polystyrene sulfonic acid, phosphoric acid, polyphosphoric acid, polyacrylic acid, a polymer, an acid, a superacid, a metal oxide, a salt and combinations thereof.

Another embodiment of this invention is directed to a CNT-containing composition, wherein the carbon nanotubes form a homogenous layer with a thickness of less than 50 nm, 40 nm, less than 30 nm, less than 20 nm, or less than 10 nm.

Other embodiments of this invention are directed to compositions as presented in varying embodiments of this invention, wherein the compositions have a sheet resistance of less than 10⁴ Ω/□, less than 10³ Ω/□, less than 10² Ω/□, or less than 10 Ω/□.

Other embodiments of this invention are directed to compositions as presented in varying embodiments of this invention, wherein the composition has a carbon purity of more than 90%, more than 95%, more than 98%, or more than 99%.

Other embodiments of this invention are directed to compositions as presented in varying embodiments of this invention, wherein the composition contains less than 5% metal, less than 3% metal, less than 2% metal, less than 1% metal, or less than 0.1% metal.

Other embodiments of this invention are directed to compositions as presented in varying embodiments of this invention, wherein the composition has stable electronic properties as measured by Ω/□ upon exposure to environmental conditions.

Other embodiments of this invention are directed to compositions as presented in varying embodiments of this invention, wherein the electronic properties change less than 50%, less than 40%, less than 30%, less than 20%, less than 10%, less than 5%, or less than 1%.

Other embodiments of this invention are directed to compositions as presented in varying embodiments of this invention, wherein the environmental conditions are extreme temperatures, humidity, or UV radiation.

Other embodiments of this invention are directed to compositions as presented in varying embodiments of this invention, wherein the composition has stable optical properties upon exposure to environmental conditions.

Other embodiments of this invention are directed to compositions as presented in varying embodiments of this invention, wherein the stable optical properties are selected from the group consisting of diffuse transparency, specular transparency, haze, diffuse reflectance, specular reflectance, and absorbance.

Other embodiments of this invention are directed to compositions as presented in varying embodiments of this invention, wherein the optical properties change less than 50%, less than 40%, less than 30%, less than 20%, less than 10%, less than 5%, or less than %.

Other embodiments of this invention are directed to compositions as presented in varying embodiments of this invention, wherein the environmental conditions are extreme temperatures, humidity, or UV radiation.

Other embodiments and advantages of the invention are set forth in part in the description, which follows, and in part, may be obvious from this description, or may be learned from the practice of the invention.

### DESCRIPTION OF THE FIGURES

FIG. 1 shows Nafion perfluorinated ion exchange resin.

FIG. 2 shows Nafion's effect on transparency.

FIG. 3 shows Nafion's effect on transparency.

FIG. 4 shows Nation's effect on resistance.

FIG. 5 shows Nation's effect on UV exposure.

FIG. 6 shows Nation's effect on UV exposure when Nafion is flow coated with Teflon AF binder, and exposure to UV radiation is effectuated for 24 hours.

FIG. 7 shows Nation's effect on heat exposure.

FIG. 8 shows the ratio of Nafion to SWnTs.

FIG. 9 shows a close up of a chart depicting the ratio of Nafion to SWnTs mixed into the SWnT ink.

FIG. 10 compares acid and non-acid polymer added to SWnT with transparency normalized to 500 Ohms/Square.

### DESCRIPTION OF THE INVENTION

The present invention describes a composite comprising a transparent, conductive layer of CNT and an additional material. It was surprisingly discovered that the added material is multifunctional; it improves one or more of the following properties of the CNT layer: sheet resistance, broad transparency to EM spectrum, specific wavelength transparency, refractive index matching, heat stability, UV stability, electromagnetic radiation stability, humidity stability, chemical stability, haze, mechanical bonding to a substrate, electrical contact with a substrate, work function control, type of charge carrier, mechanical strength, abrasion resistance.

Previous references have not discovered the surprising improvements and properties that can be achieved using the methods and compositions of this invention. For example, prior references do not disclose the combination of Nafion and SWNTs, together with the benefits other than antistatic conductivity (>10⁶ Ohms/square) and antireflective properties, the benefits of ionomers combined with SWNTs, or the benefit of Nafion to a given analyte, the volume conductivity for nanotube networks achieved in this invention (e.g. a volume conductivity of about greater than 1,000 S/cm and about less than 15,000 S/cm), and the transparency, high conductivity, and stabilizing effects of polymers with carbon nanotubes of carbon nanotube compositions when prepared according to the methods of this invention. Further, the high nanotube concentrations in a solvent, including water, as disclosed in some prior references, (i.e. a nanotube weight ratio of 1% in the ink), lead to a very thick gel or paste such as when uniformly distributed.

The utility of transparent conductive coatings for any application, such as touch screens, strongly depends on meeting a broad set of performance requirements. The primary requirements are transparency and conductivity, however to make the materials useful other properties such as mechanical adhesion to the substrate, abrasion resistance, coating uniformity, stability under radiation from the sun, stability to high temperatures experienced by the coating during processing and in use, among many others. The present invention provides additive materials which not only satisfy multiply performance requirements but also, as it was surprisingly discovered, enhance the optical and electrical performance of the CNT layer. Specifically this invention discloses a methods and materials which when added to a conductive network of nanotubes increases transparency and decreases resistivity of the network. More specifically the use of ionomeric polymer compounds as a binder or additive to the CNT network greatly improve resistance and transmission performance while reducing the deleterious effects of UV light exposure and other environmental damage. The additive polymer can be infiltrated into an existing network of CNT or can be added in to a solution of CNT and solvent for use in depositing onto any solvent compatible substrate.

In one preferred method, the CNT network is formed from a solution wherein all the compounds are fugitive except the CNT leading to a coating on the substrate which is initially purely CNT. The CNT occupy approximately 50% volume of the layer or coating on the substrate thereby creating the opportunity to fill the remaining space with a matrix or binder material which adds additional functionality to the CNT layer and can also improve the optical and electrical performance of the initial CNT network.

The additional material penetrates or infiltrates an open-pore, continuous network of CNTs. The additional material comprises acidic, fluorinated, halogenated, aminated, ionic, and sulphur-containing polymers. The properties of the composite are controlled by a selection of polymer, polymer blend, use of a copolymer, or polymer layers interpenetrating the CNT layer. Composite properties are in part controlled by the optical, thermal, mechanical, and electronic properties of the added material. Furthermore, the composite properties are tailored for a given material or combination of materials by controlling the method of deposition, amount of deposited material, film thickness, and method of curing.

In a preferred embodiment, a transparent, conductive layer of CNT is coated with an ionic polymer, and the composite is used as a transparent electrode. Suitable materials include but are not limited to Nafion and Eastman AQ55. These polymers are known to protonate carbon nanotubes.¹ Furthermore, other researchers have identified strong electrical interaction between these polymers and CNT used in sensing applications.² The interaction between the polymer and the CNT in the conductive network is beneficial to the overall goal of forming useful coatings for numerous consumer devices and military devices. The CNT-polymer composite is part of a device that requires a transparent electrode, such as a photovoltaic device, OLED, LCD, or touch screen. It was surprisingly discovered that the added polymer decreases sheet resistance and increases transparency. The use of Nafion throughout the application is not intended to be limiting, and indicates that other materials such as polymeric acids, election acceptors (e.g. Lewis acids), iodine, sulfuric acid, p-toluene sulfonic acid, nitric acid, electron donors, sodium metal, ammonia, amine, or cobaltacene, or polyethylene imine, binders, polymers, acids, metal oxides, salts, slemion, thionyl chloride, TCNQ, oxygen, water, fluoropolymeric acids, polystyrene sulfonic acids, phosphoric acids, polyphosphoric acids, polyacrylic acids, or any superacids, may also be utilized.

In another embodiment, the thickness of the composite is tuned to be about one quarter of one wavelength of light in the visible, UV or near infrared part of the spectrum. When the film is one quarter wavelength in thickness, the film is highly transparent and therefore is tuned to allow light of a certain frequency to be absorbed or emitted from the device, improving the performance of the device. The added material also improves the light and heat stability of the CNT layer.

A conductive network of carbon nanotubes is deposited onto a substrate to form a film. In a preferred embodiment, the carbon nanotubes consist of a single layer of graphene and have a diameter not greater than 3.5 nm and a length not less than 500 nm. In a preferred embodiment, the CNT film is 20%-99.9% transparent and has a sheet resistance of 0.1 Ohm/sq to 10,000 Ohm/sq. In other embodiments, the CNT film is 20%-40% transparent and has a sheet resistance of 0.01 Ohm/sq to 500 Ohm/sq. In other embodiments, the CNT film is 40%-60% transparent and has a sheet resistance of 0.1 Ohm/sq to 500 Ohm/sq. In other embodiments, the CNT film is 60%-80% transparent and has a sheet resistance of 1 Ohm/sq to 1,000 Ohm/sq. In other embodiments, the CNT film is 80%-95% transparent and has a sheet resistance of 10 Ohm/sq to 700 Ohm/sq. In other embodiments, the CNT film is 95%-99.9% transparent and has a sheet resistance of 50 Ohm/sq to 10,000 Ohm/sq.

In a preferred embodiment the substrate for depositing the CNT or CNT composite is transparent, but a transparent substrate is not a requirement for all applications. In other embodiments, the substrate is metal, ceramic, plastic, or a combination of metal, ceramic, or plastic. For example, the substrate may be glass with platinum particles deposited on the substrate. In one embodiment, the substrate incorporates refractive index matching layers to improve optical properties of the layered CNT-substrate structure. In another embodiment, the CNT is deposited onto a substrate, and the substrate is removed. In this embodiment, the CNT film is transferred to another substrate or is used as a suspended film. In one embodiment, the substrate comprises a functional material, mixture of materials, or layers of materials that absorb light and converts it to electron-hole pairs for the purpose of creating a useful current. Specifically, the substrate comprises the active materials of a photovoltaic device. In one embodiment, the substrate is rough such that it interpenetrates into the nanotube network. In another embodiment, the substrate comprises active materials that convert electricity to light, e.g. an organic light emitting diode.

The added material does not substantially form covalent bonds with the CNT sidewall, which would cause a reduction in conjugation and thus a decrease in conductivity. In a most preferred embodiment, the material added to the CNT interacts via dispersion forces and via ionic and/or donor-acceptor bonding. However, the added material may interact with the CNT ends, or defects or functional groups on the CNT ends or defects via covalent bonding. In one embodiment, the nanotube does not form covalent bonds with the added material or materials. In another embodiment, the nanotube forms mostly ionic bonds with the added material or materials.

The addition of another material to the CNT can occur at a variety of points during the production and processing of the CNT. In a preferred embodiment, the as-produced film on a substrate is exposed to another material or combination of materials to form a composite that has altered RT performance. In other embodiments, another material is exposed to CNTs while CNTs are dispersed in solution (e.g. water, alcohol, THF, DMF, other organic solvents, or mixtures of water and miscible organic solvents) or while the CNTs are solid, but not placed on the final substrate (e.g. in a container for processing, as a film suspended in air, or as a film on a disposable or removable substrate). In a preferred embodiment, the exterior of the nanotubes are coated with a material or combination of materials that interpenetrate the open pore, continuous network of CNTs.

Other material or materials are introduced to CNTs as a solid, liquid, gas, dissolved in solution, or dispersed in a liquid. Pressure, vacuum, and heat may be used to cause a phase transition to more easily incorporate the material into a formed CNT network. The other material or materials are introduced to CNTs in air, in an inert environment, in an oxidizing environment, in carbon dioxide, or in vacuum. In one embodiment, the material introduced to the nanotube film or nanotube dispersion is a liquid monomer, monomer in solution, or mixture of monomers. In the case of monomers mixed with the CNT dispersion, preferably, the two are concomitantly deposited on a substrate. In one embodiment, the substrate is dried, and the monomers react to form a polymer coating. In another embodiment, the deposited film remains wet, and the monomers react to form a polymer coating. In the case in which the monomers are deposited after the CNT layer has formed, the monomers are deposited wet and are optionally allowed to dry prior to polymerization. The monomers are preferably polymerized by heat, light, UV, a catalyst, or a combination of these initiators.

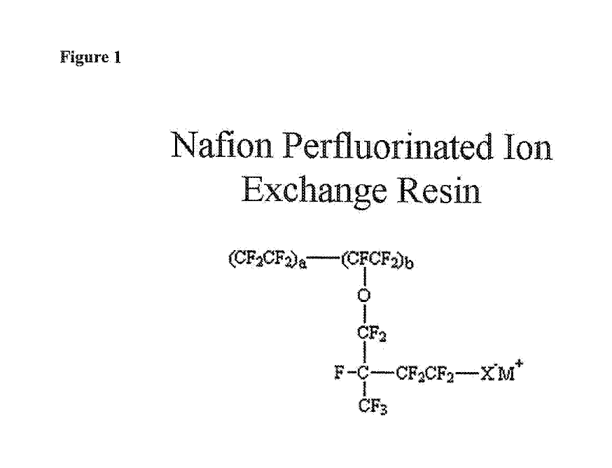

In a preferred embodiment, the CNT composite comprises a polymer interpenetrated into the nanotube network. In one embedment, the plastics may be thermosets, thermoplastics, elastomers, conducting polymers, and combinations thereof. In a further preferred embodiment, the polymer is a fully or partially halogenated polymer that is optically transparent. In another preferred embodiment, the polymer is acidic. In another embodiment, the polymer is ionic. Optionally, acidic polymers may be neutralized by cation exchange. Further, cations may include Na, K, Rd, Ca, Mg, Zn, Ag, Fe, lanthanides, transition metals, charged nanoparticles, cationic surfactants, cationic polymers, organic cations, or combinations thereof. In a preferred embodiment, the polymer is conductive. hi a further preferred embodiment, the polymer is acidic and halogenated. In a most preferred embodiment, the polymer is Nafion, a fully fluorinated, sulfonic acid polymer. Nafion can also be described as a strong polymeric acid immersed in a fluoropolymer matrix, capable of making a clear film, a solution in water and alcohol. Dry Nafion film absorbs water and some polar organics. Other Nafion properties include a continuous operating temperature of 175 C, ESD level conductivity, and the ability to not be damaged by sunlight. FIG. 1 shows Nafion perfluorinated ion exchange resin.

In other embodiments, polystyrene sulfonic acid (PSS), Eastman AQ 29, AQ 38, AQ 48, AQ 55, or other acidic and/or ionic polymers are added to CNT layers. In other embodiments, the polymer may be mixed with other polymers, such as PEDOT, to enhance adhesion, uniformity, optical or electrical properties. Optionally, polymers are added sequentially to the CNT layer. The sequential addition of polymers may be used to improve specific properties, such as humidity or UV resistance. The range of polymers that can be added sequentially is substantially broader and includes all classes or polymers listed above, conjugated polymers, ceramic polymers, ceramic hybrid polymers, polyethylene, polypropylene, polyvinyl chloride, styrenes, polyurethane, polyimide, polycarbonate, polyethylene terephthalate, cellulose, gelatine, chitin, polypeptides, polysaccharides, polynucleoutides, and mixtures thereof. In one embedment, the plastics may be thermosets, thermoplastics, elastomers, conducting polymers, and combinations thereof. Other additives may be included in the polymer or added sequentially to improve the functional properties of the CNT layer or coating. Additionally, the CNTs may be been previously treated with another material that resides in the CNT interior cavity.

The added polymeric material can be deposited in a variety of ways. If the polymer is soluble, it may be deposited onto the CNT layer from solution. In a preferred embodiment, the weight % of the polymer in solution is 1%-25%. In another embodiment, the weight % of the polymer in solution is 10%-25%. in another embodiment, the weight % of the polymer in solution is 5%-10%. In another embodiment, the weight % of the polymer in solution is 3%-5%. In another embodiment, the weight % of the polymer in solution is 1%-3%. In another embodiment, the weight % of the polymer in solution is 0.1%-1%. In another embodiment, the weight % of the polymer in solution is 0.005%-0.1%. The polymer solution is preferably deposited by dip coating, drop coating, kiss coating, gravure coating, screen printing, ink jet printing, roll coating, pad printing, knife coating, spin coating, spray painting, electrostatic painting or other techniques known to those skilled in the art.

In a preferred embodiment, the CNT composite has lower sheet resistance, compared to the CNT without polymer. In a preferred embodiment, the sheet resistance is 90% to 10% lower than a comparable CNT layer or coating without polymer. In another embodiment, the sheet resistance is 90% to 75% lower than a comparable CNT layer or coating without polymer. In another embodiment, the sheet resistance is 75% to 50% lower than a comparable CNT layer or coating without polymer. In another embodiment, the sheet resistance is 50% to 35% lower than a comparable CNT layer or coating without polymer. In another embodiment, the sheet resistance is 35% to 20% lower than a comparable CNT layer or coating without polymer. In another embodiment, the sheet resistance is 20% to 15% lower than a comparable CNT layer or coating without polymer. In another embodiment, the sheet resistance is 15% to 10% lower than a comparable CNT layer or coating without polymer. In another embodiment, the sheet resistance is 10% to 5% lower than a comparable CNT layer or coating without polymer.

In a preferred embodiment, the CNT composite has improved broad spectrum transparency (e.g. transparency to UV, IR and visible wavelengths), compared to a CNT layer without polymer. The improvement in transparency is a consequence of low refractive index of the polymer, antireflective properties of the added polymer, and reduction of haze of the film. Thus the polymer reduces scattering of light occurring in the layer or coating and reflection off its surface. In a preferred embodiment, the added polymer improves the transparency of the film in the full visible region. In a preferred embodiment, the added polymer improves the transparency of the film in the full visible region by 1-20%, compared to a CNT layer without polymer. In another embodiment, the added polymer improves the transparency of the film in the full visible region by 15-20%, compared to a CNT layer without polymer. In another embodiment, the added polymer improves the transparency of the film in the full visible region by 10-15%, compared to a CNT layer without polymer. In another embodiment, the added polymer improves the transparency of the film in the full visible region by 8-10%, compared to a CNT layer without polymer. In another embodiment, the added polymer improves the transparency of the film in the full visible region by 5-8%, compared to a CNT layer without polymer. In another embodiment, the added polymer improves the transparency of the film in the full visible region by 3-5%, compared to a CNT layer without polymer. In another embodiment, the added polymer improves the transparency of the film in the full visible region by 3-5%, compared to a CNT layer without polymer. In another embodiment, the added polymer improves the transparency of the film in the full visible region by 1-3%, compared to a CNT layer without polymer. In another embodiment, the added polymer improves the transparency of the film in the full visible region by 0.1-1%, compared to a CNT layer without polymer or additional material as the binder.

In a preferred embodiment, the CNT composite has improved specific wavelength transparency, compared to a CNT layer on a substrate without polymer. This effect is achieved by controlling the thickness of the composite support on a higher index of refraction substrate, such as glass or PET film. While not bound by theory, when the thickness of the composite is approximately one quarter of a given wavelength of light and has a index of refraction which is lower than the substrate, the film becomes highly transparent (greater than or equal to 100% transparency) to that wavelength. This effect can be used to optimize the performance of a device, such as a photovoltaic device or an OLED. In a preferred embodiment, the thickness of the composite is tuned to match specific wavelength transparency of the optical emission or absorbance of the active material in a device. In a further preferred embodiment, the film has specific wavelength transparency for the bandgap or to a higher energy (having a shorter wavelength) than the bandgap of a photovoltaic device. In another preferred embodiment, the film has specific wavelength transparency for the emission wavelength of an OLED. In another embodiment, the composite thickness is optimized to be about a quarter of the wavelength of the maximum energy of the solar spectrum. In another embodiment, the composite thickness is optimized to be maximally transparent at about the wavelength of the maximum energy of the solar spectrum. In another embodiment, the composite thickness is chosen to optimize the performance of a device.

In a preferred embodiment, the CNT composite has improved heat stability below 150 degrees C., UV stability, and light radiation stability, compared to CNT without polymer. The stability is attributed to any one or combinations of a variety of effects including: oxidation of the CNTs, steric protection of the CNTs, displacement of the possible reactants with a more inert polymer, absorption of a damaging radiation, mechanically binding the nanotubes to the substrate, mechanically binding the nanotubes to each other, increasing robustness of the film to differences in coefficients of thermal expansion, and combinations thereof In one embodiment, UV and light stabilizers are added to the polymer. hi a preferred embodiment, the sheet resistance of the composite changes 60% or less upon exposure to heat less than 150 degrees C., light, or UV. In a further preferred embodiment, the sheet resistance of the composite improves 50% or less upon exposure to heat less than 150 degrees C., light, or UV. In another embodiment, the sheet resistance of the composite changes 120% or less upon exposure to heat less than 150 degrees C., light, or UV. In another embodiment, the sheet resistance of the composite changes 100% or less upon exposure to heat less than 150 degrees C., light, or UV. In another embodiment, the sheet resistance of the composite changes 80% or less upon exposure to heat less than 150 degrees C., light, or UV. In another embodiment, the sheet resistance of the composite changes 70% or less upon exposure to heat less than 150 degrees C., light, or UV. In another embodiment, the sheet resistance of the composite changes 60% or less upon exposure to heat less than 150 degrees C., light, or UV. In another embodiment, the sheet resistance of the composite changes 50% or less upon exposure to heat less than 150 degrees C., light, or UV. In another embodiment, the sheet resistance of the composite changes 40% or less upon exposure to heat less than 150 degrees C., light, or UV. In another embodiment, the sheet resistance of the composite changes 30% or less upon exposure to heat less than 150 degrees C., light, or UV. In another embodiment, the sheet resistance of the composite changes 20% or less upon exposure to heat less than 150 degrees C., light, or UV. In another embodiment, the sheet resistance of the composite changes 10% or less upon exposure to heat less than 150 degrees C., light, or UV. In another embodiment, the sheet resistance of the composite changes 5% or less upon exposure to heat less than 150 degrees C., light, or UV.

In a preferred embodiment, the CNT composite has improved humidity stability and chemical stability as compared to CNT composites in the absence of additives of the invention. The stability is afforded by steric protection of the CNTs by the polymer, hydrophobicity of the polymer, chemical stability of the polymer, preferential reactivity of the polymer, and combinations thereof In one embodiment, an additional coating of polymer is added to the CNT composite to improve humidity and chemical stability. The stabilizing polymer is added sequentially or concomitantly with another polymer. In the case of sequential addition, the other polymer may be in the form of a film or sheet added to the top of the CNT composite.

In a preferred embodiment, the CNT composite has improved mechanical bonding to a substrate, mechanical strength, and abrasion resistance as compared to CNT composites in the absence of additives of the invention. The improved mechanical properties are a consequence of the polymer interpenetrating the CNT network to add mechanical reinforcement. Binding to the substrate is improved by the polymer forming a dispersive, van der Wools interaction with the substrate. Alternately, the surface may be functionalized to increase bonding of the polymer with the substrate by covalent bonding, ionic bonding, charge transfer, hydrogen bonding, and combinations thereof, including van der Wools bonding. The polymer contributes to the composite's mechanical robustness, compared to CNTs with polymer. The composite has improved tensile strength and abrasion resistance. Abrasion resistance can be further improved by concomitantly or sequentially adding metal oxide particles. Abrasion resistance can also be improved by sequentially adding another anti-abrasion material.

In a preferred embodiment, a CNT network is employed as the transparent electrode in a solar cell. Amorphous silicon, CIGS, CdS, Graetzel, organic, exitonic, multijunction, and quantum dot-based solar cells all require a transparent electrode. In all cases, electron-hole (e-h) pairs are created from photons in the active material(s) and must be transported to different electrodes before recombining. In this preferred embodiment, one of the electrodes of a solar cell must be transparent.

Each solar cell mentioned herein has unique electronic properties and responses to light and thus has different requirements for transparent electrodes. These requirements include at least: broad spectrum transparency, transparency at a specific wavelength or a narrow range of wavelengths, conductivity, work function match, type of charge carrier, and contact area to the active material. Ideally, a transparent electrode would have maximum transparency over a broad spectrum to create the largest amount of e-h pairs possible. Also, the transparent electrode would have maximum conductivity to turn the maximum amount of e-h pairs into useable current. Other considerations include the effect of work function matching, the type of charge carrier to be transported to the electrode, and the area of contact between the transparent electrode and the active material. Adding another material to the transparent, conductive CNT layer can tune all of these properties, which can give additional efficiency of the solar cell that is beyond what would be realized just by improving resistance and/or transparency of the transparent electrode.

In a preferred embodiment, the composite CNT material used as a transparent electrode gives greater conversion of solar energy to electrical energy, as compared to using only a CNT film. In a further preferred embodiment, the CNT composite causes additionally improved solar efficiency due to work function matching with the active layer. Work function matching is achieved by adding a material to the CNT film that changes the work function of the CNT composite. The degree of work function change is controlled by the amount of added polymer, the type of added polymer, and by combining different polymers or using copolymers.

In a further preferred embodiment, the added material or dopant increases the number of charge carriers most useful to the cell design. For example, CIGS and Graetzel solar cells transport electrons to the transparent electrode. CNTs are p-doped in air, but would be more efficient as n-doped materials to conduct electrons. CNTs are converted to n-type conductors by doping with a Lewis base, incorporating electron donating materials, incorporating nitrogen-containing polymers, such as polyethyleneimine and combinations thereof. As another example, exitonic solar cells transport holes to the transparent electrode. Therefore, a greater number of holes contributing to CNT conductivity would enhance current through the cell and thus increase efficiency. Roles are added by doping with a Lewis acid, by incorporating a halogenated polymer, an acidic polymer, an acidic fluoropolymer, such as Nafion, and combinations thereof into the CNT network.

The addition of polymer improves composite conductivity and improves physical and electrical contact with the active material. Improved mechanical contact between the CNT composite and the active material enhances solar cell durability. In a preferred embodiment, the polymer is conductive and assists in transporting charge to the CNT network. The improved conductive contact area of the CNT composite enhances solar cell efficiency, compared to a transparent electrode made only of CNTs. The increased efficiency is a consequence of greater probability for conduction of a photogenerated electron or hole. In a further preferred embodiment, Nafion is added to CNT films, improving the transparent electrode RT performance and enhancing hole conductivity at the active layer-transparent electrode interface.

Properties of Nafion that have been tested for purposes of this invention are at least transparency, effect on sheet resistance (measured by Ohms/Square), effect on UV exposure, effect on heat, and application methods. Application methods for Nafion include dip coating, flow coating SWnT samples, (demonstrated from samples made for heat and UV testing), and adding Nafion directly to the SWnT ink before spraying.

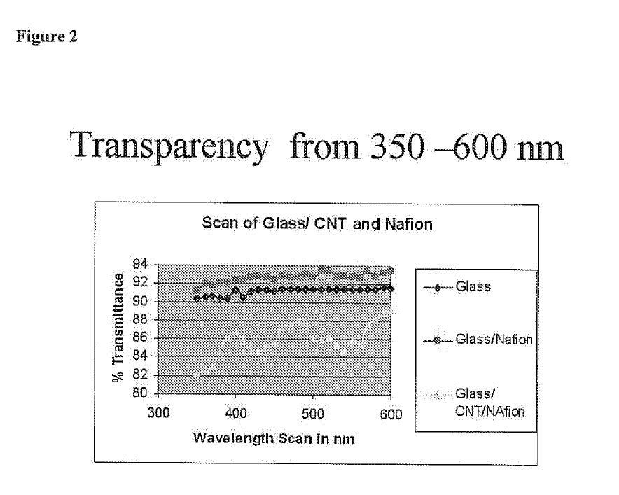

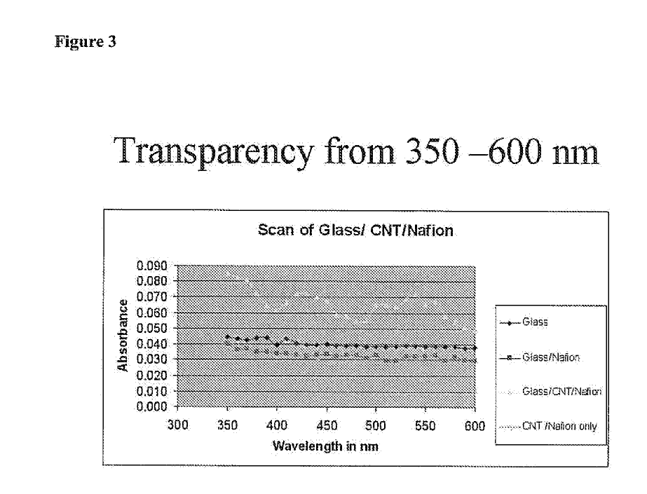

FIGS. 2 and 3 show Nafion's effect on transparency. In experiments conducted, 5% Nation solution was flow coated onto substrate and acted as an antireflective coating. Lower concentrations below 0.5% maintained or increased the original transparency values. No reduction in transparency was experienced.

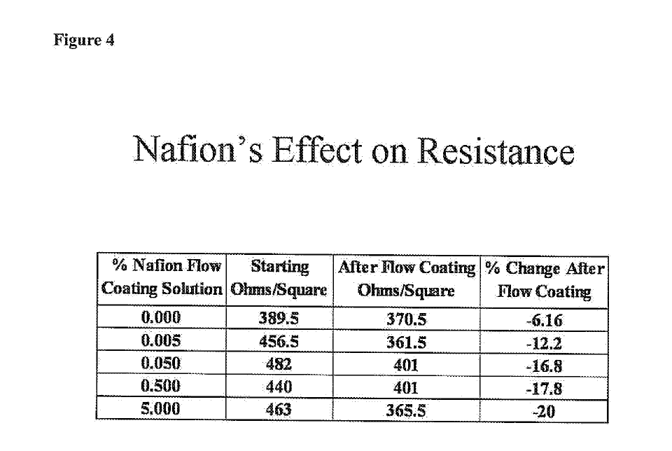

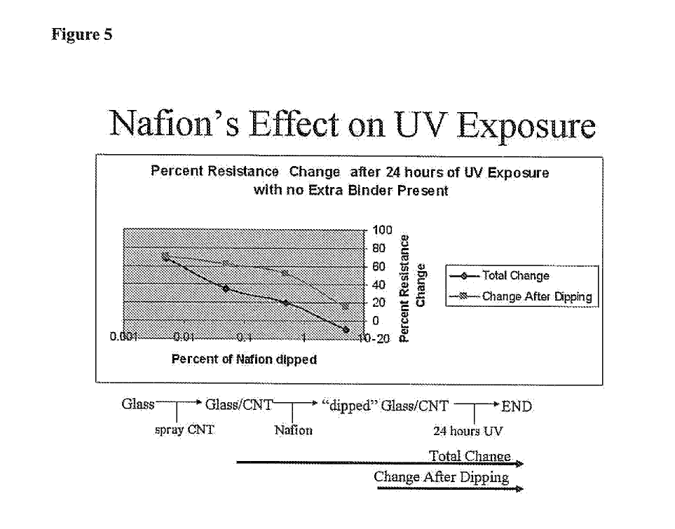

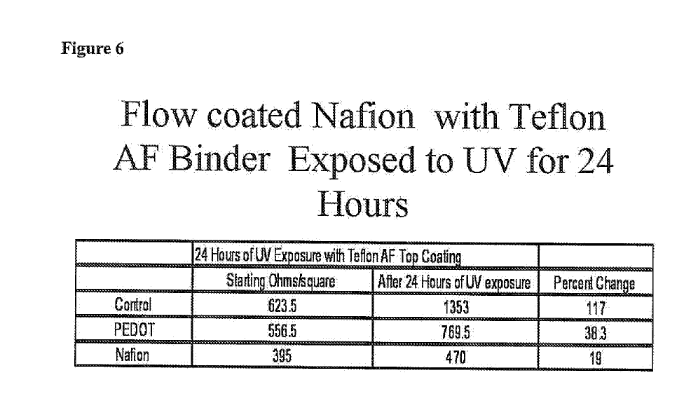

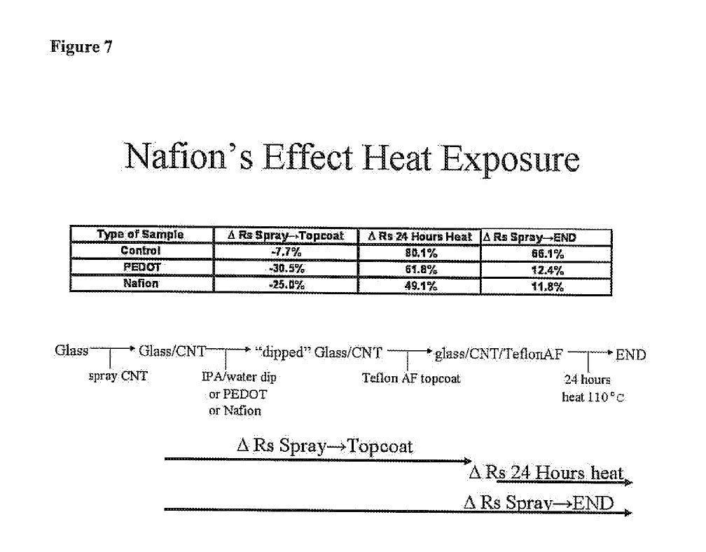

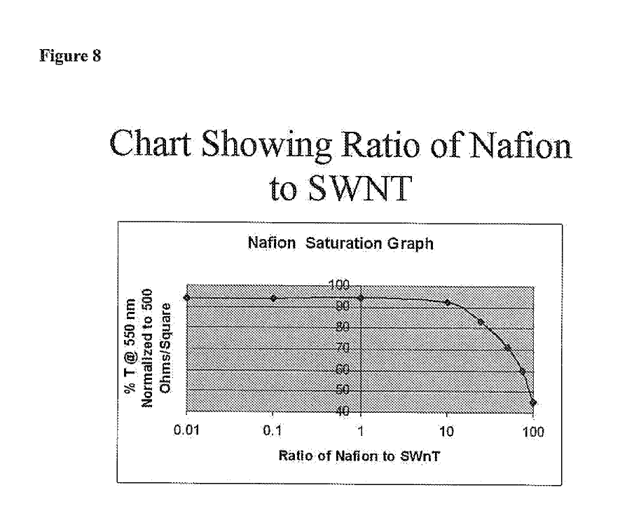

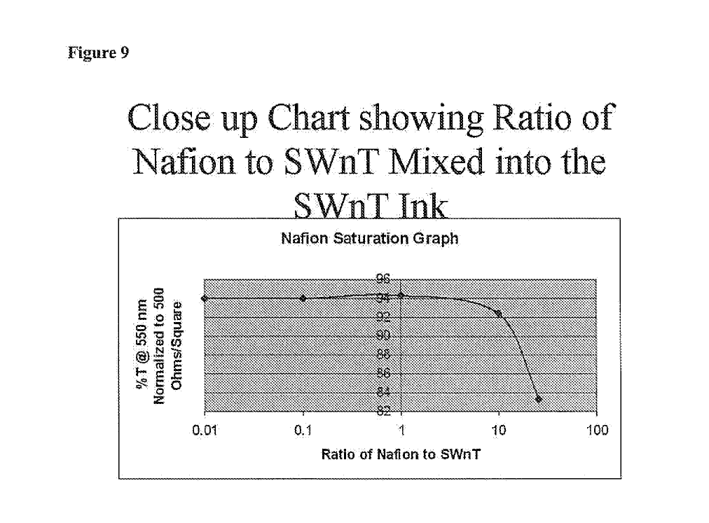

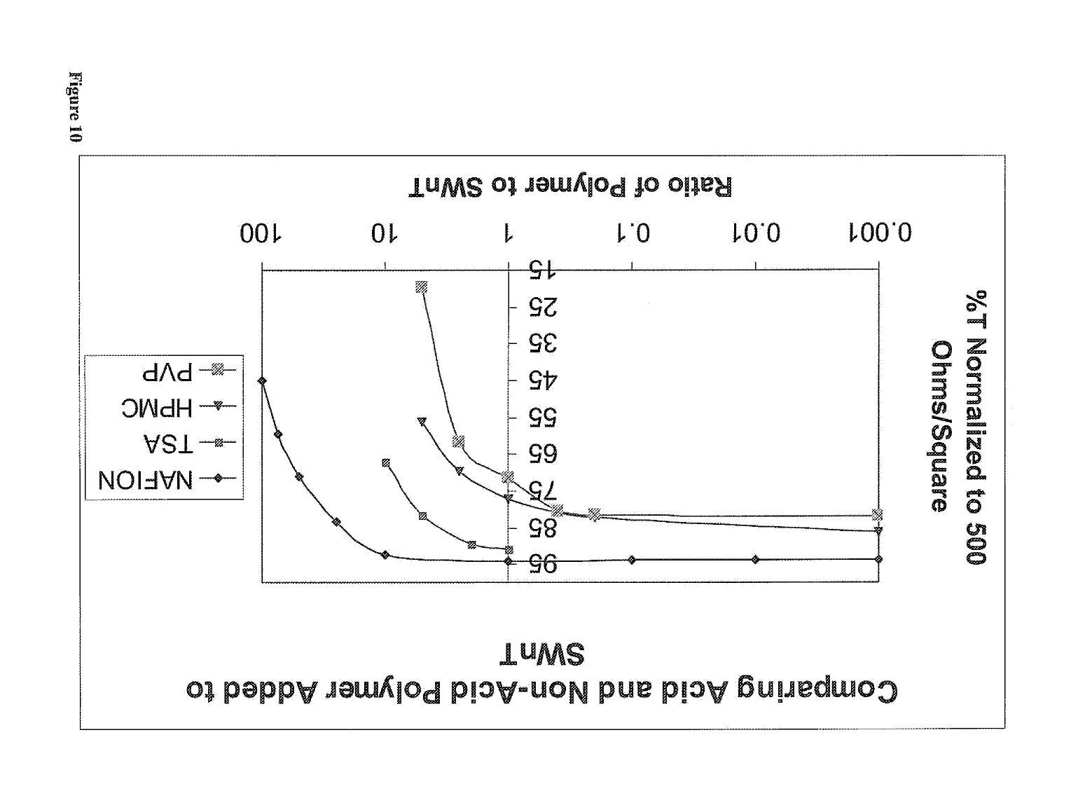

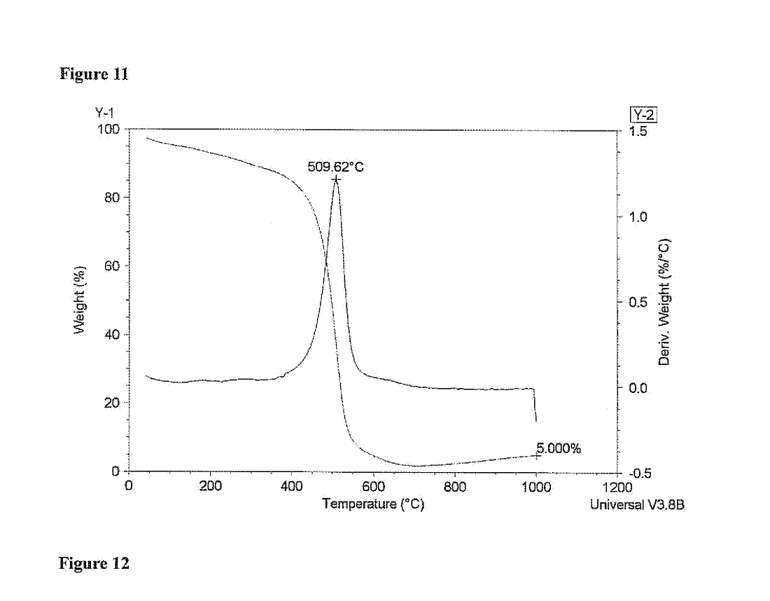

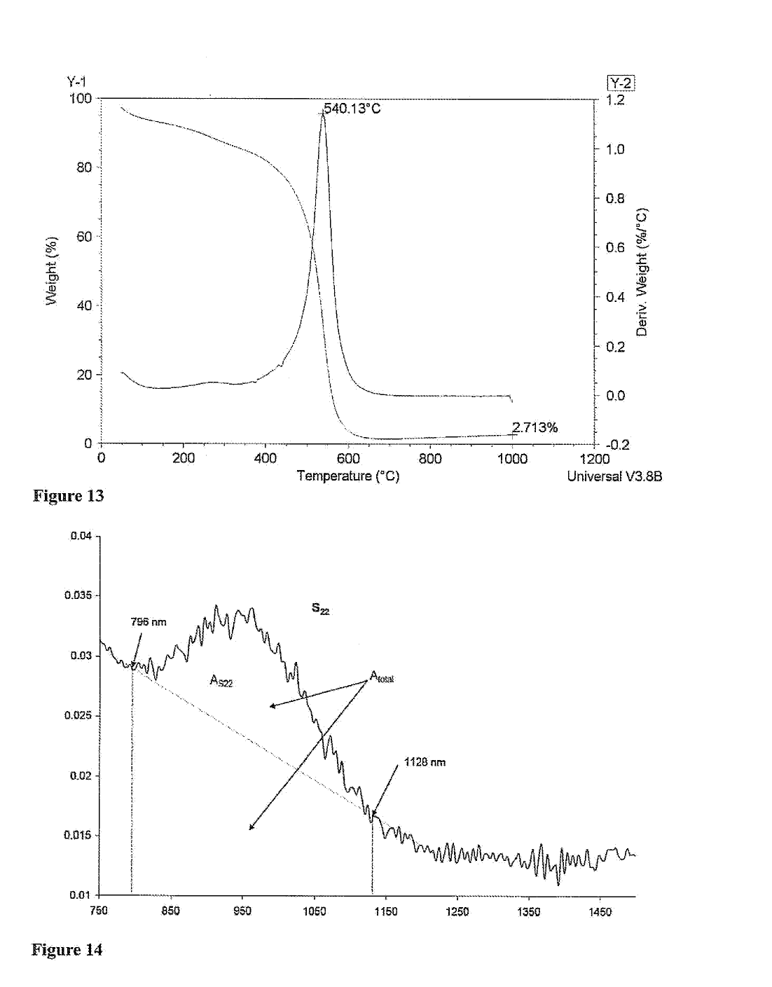

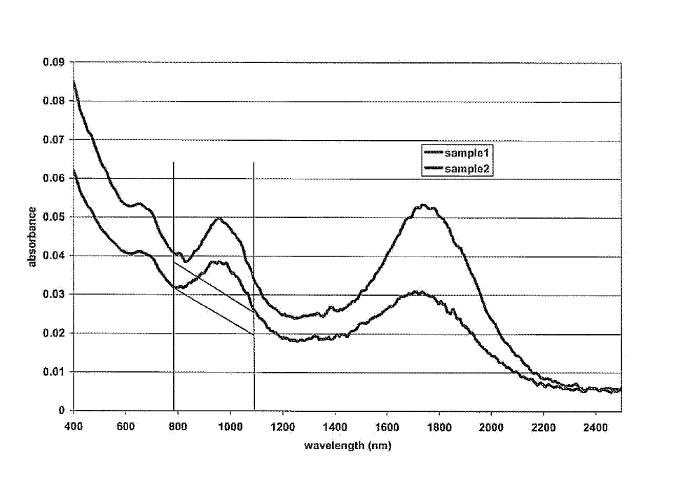

FIG. 4 shows Nafion's effect on resistance. FIG. 5 shows Nafion's effect on UV exposure. FIG. 6 depicts the protection afforded by flow coated Nafion with Teflon AF binder to exposure to UV radiation for 24 hours. FIG. 7 shows Nafion's effect on heat exposure. FIG. 8 is a chart showing the ratio of Nation to SWnTs and transparency normalized to 500 Ohms/Square. FIG. 9 is a close up chart showing the ratio of Nation to SWnT mixed into the SWnT ink. FIG. 10 compares acid and non-acid polymer added to SWnT, with transparency normalized to 500 Ohms/Square.

In other embodiments, the change in work function of the CNT composite is beneficial to OLEDs and improves the OLED efficiency at emitting light. In one preferred embodiment, the work function of the CNT composite is decreased to use the CNT composite as an electron injecting electrode in an OLED device. The change in work function will benefit LCD displays using transparent electrodes. The work function of the CNT composite can be adjusted to be close to the work function of a reflective pixel electrode in an LCD. An improvement in electroluminescent (EL) lamp lifetime and/or brightness occurs when using CNT composites as the transparent electrode described in this disclosure, as compared to bare CNT electrode or other organic alternatives. In one embodiment, the work function of the CNT composite is chosen to “build in” a potential difference between two electrodes in a device. The built in potential causes or encourages flow of charge in one direction, which improves the performance of devices.

Changing the charge carriers of the CNT composite to make the material a p-type conductor or an n-type conductor is useful for some applications beside solar cells. Most transparent conductive oxides (TCOs) are n-type conductors. P-type TCOs have much lower conductivities, and therefore are not used to make transparent circuit elements. It is possible to integate CNTs with TCOs to make heterostructures, but similar effects can be achieved by changing the carriers in CNT networks. Transparent p-n junctions, transistors, diodes, including light emitting diodes can be fabricated with CNT composite acting as one of the materials. Also, smart windows can take advantage of different carriers or CNT composites with different work functions in the transparent conductors.

One preferred method of treating CNTs with Nafion is a two-step process, in which first the CNTs are laid down on a substrate, and then Nafion is deposited onto said CNT layer, Another preferred method of using Nafion is by adding small amounts of Nafion in a CNT-containing solution, and then depositing the Nation and CNT-containing solution onto a substrate. Preferably, when Nafion is added directly to a CNT-containing solution, the Nafion is present in less than a 1:1 ratio. If a thicker Nafion layer is desired, it is preferable to achieve it through the two-step procedure so that Nafion will not interfere with the conductive network.

The surprisingly superior conductivity of CNT-containing compositions in this invention may be preferably achieved through at least a combination of factors such as quality, purity, density and thickness of the CNT networks. Preferably encompassed in the quality factor is a maximization of the ability of the carbon nanotubes to rope, which enhances electronic properties. Conductivity of the carbon nanotube composite is also reduced by the presence of breaks in carbon nanotubes producing shortened and smaller lengths of tubes. By narrowing the diameters of carbon nanotube ropes, there is an enhancement of a carbon nanotubes-containing composites's transparency at any given resistivity. Roping ability is improved with decreased diameter of the carbon nanotubes. By minimizing such breaks, there is an enhancement of the carbon nanotubes' ability to form conductive composites. Quality is preferably achieved through a purification procedure which removes non-CNT impurities such as residual catalysts, metals such as, for example, metal oxides, other forms of carbon, such as, for example, graphite, amorphous carbon, broken tubes, etc. Disentanglement processes are also preferably performed to remove flocculation and/or agglomerates or lumps of CNTs. Impurities may also block light, thereby affecting transparency. Purity processing therefore preferably improves (increases) transparency of CNT-containing compositions, preferably by minimizing optical absorption.

CNTs can be metallic or semi-conducting. CNTs in embodiments of this invention preferably exhibit metallic behavior, and more preferably exhibit this behavior with essentially no metal content. Preferably, embodiments of this invention's CNT-containing films are very thin. Preferably, CNT-containing compositions of this invention have a greater than 50% transparency (T), greater than 60% T, greater than 70% T, greater than 80% T, greater than 90% T, greater than 95% T, or greater than 99% T. Sheet resistance is preferably lower than 5×10⁴ Ω/□, lower than 10⁴ Ω/□, lower than 10³ Ω/□, lower than 10² Ω/□, lower than 10 Ω/□, lower than 1 Ω/□, lower than 10⁻¹ Ω/□, lower than 10⁻² Ω/□, lower than 10⁻³ Ω/□, and lower than 10⁻⁴ Ω/□.

In preferred embodiments of this invention, Nafion and like substances are used in combination with other binders to produce a synergistic improvement of optical, electrical, and resistance/stability to environmental factor improvement. The effects of such synergisms produces better electronic/optical/stabilized properties than achieved by metal oxides.

Preferably, CNT-containing compositions of this invention are homogenous, preferably as evinced by optical tests (for example, with electron microscopy (SEM or TEM)), ultrasonic tests, or high sheer mixing. Preferably, CNT-containing compositions of this invention achieve molecular perfection.

Preferably, the sheet resistance of CNT-containing compositions of this invention is less than 400 Ω/□, preferably for a CNT coating that is one layer thick, preferably 1-2 ropes thick, also preferably 1-5 ropes thick or less than 10 ropes thick.

In a preferred embodiment, thickness measurements of a 50 Ω/sq SWNT film (˜60% T) were made on films using an atomic force microscope by imaging over an area with a scratch from a razor blade. Line averaging thickness over 2 μm of a 50 Ω/sq layer yielded a thickness of 40 nm with an RMS (i.e. root mean square) roughness of ±31 nm. A 100 Ω/sq film (˜84% T) was 30 urn thick with an RMS roughness of ±26 nm. Based on the measured sheet resistances and thickness, a coarse volume is on the order of 3,300 to 5,000 S/cm. Assuming a 50% void space, the fully dense networks have a volume conductivity of 10,000 S/cm to 6,600 S/cm. No metallic impurities were detected with Energy Dispersive Spectrometers (EDS), Auger Electron Spectrometers (AES), or X-Ray Photoelectron Spectrometers (XPS).

As-prepared SWNTs (AP-SWNTs) are typically contaminated with amorphous carbon (AC), catalysts, and graphitic nanoparticles (CNPs). Amorphous carbonaceous impurities (AC) have been removed by nitric acid reflux, sulfuric-nitric acid reflux, H2O2 reflux, refluxing in other oxidizing acids, refluxing in combinations of these acids, and sonication in one or combinations of these acids. Air oxidation, CO oxidation, CO2 oxidation, or other oxidizing gasses have been used to remove amorphous carbon impurities. HCl and other acids dissolve metallic catalyst. AP-SWNTs have been refluxed HCl and other acids to dissolve metal catalyst. Metal catalyst has been removed by dissolution in acid and later decantation or filtration of the mixture. AC preferentially suspends in aqueous media and therefore may be separated from the SWNTs by centrifugation and decantation, membrane filtration, or cross-flow filtration. Preferred centrifugation forces are between 500 g and 10,000 g. Preferred pore sizes for filtration are between 100 microns and 0.2 microns. Carbon nanotubes have been further purified to remove CNPs, if present in the initial sample, by creating a uniform dispersion, and separating the CNPs from the SWNTs by centrifugation and decantation, membrane filtration, or cross-flow filtration. Preferred centrifugation forces are between 500 g and 100,000 g. Preferred pore sizes for filtration are between 100 microns and 0.2 microns. SWNT dispersion has aided by functionalization of the nanotube ends or sidewalls, or ends and sidewalls, by polymer wrapping, by surface active agents, by charging, by colloid formation, by viscous solvents. Noncovalent additives have been removed by selective precipitation of SWNTs from solvents, by rinsing SWNT films, by addition of competitive solvents, by colloid-breaking or surface active agent breaking additives, by thermal annealing, by oxidation above the oxidation temperature of the additive, and by washing with alcohol, by washing with water, or by addition of salts. Preferred solvent media for purification of SWNTs are water, alcohol, diols, ketones, DMF, DMSO, NMP, THF, polar aprotic solvents, aliphatic compounds, methanol, ethanol, isopropanol, butanol, ethyl acetate, propylene glycol, ethylene glycol, thermoplastics, and combinations thereof. In preferred embodiments, mixed solvents are miscible. In other embodiments, mixed solvents for a colloid. In other embodiments, missed solvents form two phases with impurities separating to one phase and SWNTs to the other phase. The purification methods described herein not limited to SWNTs are applicable to double walled nanotubes, few walled nanotubes, and multiwalled nanotubes.

Purification that removes metal as measured by EDS, ABS or XPS preferably achieves greater than 90% CNT purity, greater than 95% purity, greater than 97% purity, greater than 98% purity, greater than 99% purity, and 100% purity.

The following examples illustrate embodiments of the invention, but should not be viewed as limiting the scope of the invention.

### EXAMPLES

### Examples #1 and #2 Nation and Transparency

Three samples were prepared for testing. Sample 1 was a cleaned glass slide. Sample 2 consisted of a clean microscope slide with a flow coated 5% Nafion applied with 15 minutes of heating at 100 C to remove solvents. The third sample consisted of a clean glass slide with a dispersion of SWnT in 3:1 IPA /water sprayed onto the glass slide to 490 Ohms/Square at 93.5% T % 550 nm. The side coated with SWnT was then flow coated with 5% Nation in the same manner as the Nafion only slide. The sample was then heated at 100 C for 15 minutes. The properties of the SWnT/Nafion slide were 399.5 Ohms/Square at 93.8% T % 550 nm. All three samples were measured in a Perkin-Elmer Lambda 3B.

### Example #3 Nation Effects on Resistance

Five clean glass slides were spray coated with dispersion SWnT in 3:1 IPA/Water. The Rs values for the samples were between 380-490 Ohms/Square measured using the silver paint two-point method. The two-point resistance measurement consists of applying silver paint across a 1×3 inch slide, so that the measurement is made over a 1×2 inch area. To determine ohms/Square of the sample, the resistance number is divided by 2. The solutions for the experiment were made by diluting a 5% stock solution of Nation with 1:1 IPA/Water to make the different concentrations of Nafion, The % Nafion solutions that were used were as follows: Control (1:1 IPA/Water), 0.005%, 0.05%, 0.5% and 5.0% Nation. Each sample made was flow coated with one of the solutions and allowed to air dry before heating in an oven at 100 C for 15 minutes. After cooling the samples were measured for resistance change.

### Example 144 Nation Effects on UV Exposure

Samples for Example 3 were measured for resistance (Ohms/Square) and then placed in an ultra violet exposure chamber. The chamber consisted of a PVC tube with 4-foot florescent light fixtures attached inside the tubes. The florescent light bubbles used were Q Panel UVA 340, which were placed in the chamber so that the samples were less than 2 inches from the bubbles. The resistance measurements were done by first removing the samples from the chamber and then waiting five to ten minutes before taking measurements. The results were reported from the as sprayed resistance value and also the resistance value after the flow coating. Both values are important as Nafion dopes the SWnT film lowering the resistance of the coating. The graph shows both the “as sprayed” percent resistance change and after Nafion coated resistance change for 24 hours of UV exposure. The “as sprayed” values are calculated from the initial sprayed value to the ohms/Square measurements after 24 hours of UV exposure. The change after dipping percent change is calculated from after Nafion dipping and the value after 24 hours of UV exposure. The differences in the two graphs are due to the doping of the SWnT coating with Nafion. Both of the graphs show increased protection from UV exposure with increasing concentrations of Nafion.

Example #5 and 6 Nafion UV and Heat Exposure

Samples were made on clean (1×3) inch glass slides that were sprayed with a dispersion of SWnT in 3:1 WA water. The control sample was dipped into a solution of 3:1 WA/Water, no coatings applied to the sample. The dipping of the control (bare SWnT) made the dipping process not a factor in the experiment. The PEDOT sample was dipped in 3% solutions of Bayer PEDOT solution. After drying, the sample was dipped in a 0.25% concentration of Teflon AF. The Nafion sample was dipped in a 5% solution of Nafion and, after drying, was dipped into a 0.25% Teflon AF solution. Both coated samples were heated at 100 C for 15 minutes to remove any solvents. Samples were measured for resistance (Ohms/Square) and then placed in an ultra violet exposure chamber. The chamber consisted of a PVC tube with 4-foot florescent light fixtures attached inside the tubes. The florescent light bubbles used were Q Panel UVA 340, which were placed in the chamber so that the samples were less than 2 inches from the bubbles. The samples were removed from the chamber and the resistance measurement made after 5-10 minutes. The data shows the percent resistance change from after dipping of the sample to 24 hours after exposure to the UV lights. The bare (Control) CNT changed 117%, the PEDOT sample changed 38.3%, and the Nafion coated sample changed 19%.

### Example 7 Heat Experiment

The samples were made in the same manner as the UV samples except the resistance change from dipping was recorded. The samples were heated for 24 hours in an oven at 110 C and then after the samples cooled for 5-10 minutes the resistances were recorded. The values for this experiment were calculated from the “as sprayed” resistance values and from the “after dipping” values. The data clearly showed protection from heat compared to bare SWnT films.

### Example 8 Nation added to CNT ink

CNT ink was prepared from CNT paste using standard techniques. Purified Are SWNTs were dispersed in alcohol and water to an absorbance of about I. The ink was prepared to hit a target of absorbance equal to unity (1). The ink was then divided into aliquots for addition of varying amounts of Nafion. A concentrated solution of Nafion in standard ink solvents was added to each aliquot so that the mixture contained a well defined ratio of CNT: Nafion. Each aliquot of ink was sonicated before coating and was sprayed onto glass slides to approximately 500 Ω/□. The transparency and conductivity were measured, and the transparency was renormalized to 500 Ω/□. The addition of Nation did not affect ink stability. Inks were stable for several hours and during spray coating. Nanotube to polymer ratios refer to dry weight of CNT and dry weight of polymer. The CNT ink concentration is typically 30 mg per liter at absorbance 1.

### Example 9 Polystyrene Sulfonic Acid (PSS) Added to CNT Ink

CNT ink was prepared from CNT paste using standard techniques. Purified Arc SWNTs were dispersed in alcohol and water to an absorbance of about 1. The ink was prepared to hit a target of absorbance equal to unity (1). The ink was then divided into aliquots for addition of varying amounts of PSS. A concentrated solution of PSS in standard ink solvents was added to each aliquot so that the mixture contained a well defined ratio of CNT: PSS. Each aliquot of ink was sonicated before coating and was sprayed onto glass slides to approximately 500 Ω/□. The transparency and conductivity were measured, and the transparency was renormalized to 500 Ω/□.

As can be seen from Table 1, the addition of PSS does not have a significant effect on resistance-transparency (RT) performance vs. the control, which is CNT ink without PSS. An appreciable effect RT performance begins at a ratio of PSS:CNT of 5:1, which is a significantly higher loading than possible for most polymers. Thus, it can be inferred that the PSS has a neutral effect, i.e. that it does not interact with the nanotubes, or that the PSS is improving the nanotube conductivity by doping while decreasing the inter-bundle connectivity by wrapping the CNTs. It is difficult to tell which mechanism is at play without a more careful investigation into chemical shifts or doping effects. Ink was stable and did not flocculate with the addition of Nation.

TABLE 1
Ratio of PSS:CNT vs. transparency at 500 Ω/□.

| Ratio of PSS:CNT | % T @ 500 Ω/□ |
|---|---|
| 0 | 86.7 |
| 0.2 | 85.4 |
| 0.4 | 85.7 |
| 1 | 87.3 |
| 2.5 | 83.7 |
| 5 | 72.5 |

### Example 10 Toluene Sulfonic Acid Sodium Salt (TSA) Added to CNT Ink

Toluene sulfonic acid was added to CNT as a monomer analogue to PSS. TSA was added to ink in a similar fashion to that described above. In these experiments, the TSA was added in higher concentrations to determine how much loading was considered to be detrimental.

As can be seen from Table 2, the RT performance of the ink degraded only at or above a fivefold excess of TSA. At higher TSA loading, the slides appeared to be hazy, which indicated that the TSA was deposited as a polycrystalline film with the CNTs. The slides were rinsed with DI H₂O to remove the TSA. It was found that the sheet resistance dropped in all cases, and the transparency increased. The combination of both factors led to significantly higher RT performance, with all samples at approximately 91% T at 500 Ω/□ after rinsing. Ink was stable and did not flocculate with the addition of acid.

TABLE 2
Ratio of TSA:CNT vs. transparency at 500 Ω/□ for sprayed and
rinsed samples.

| | % T @ 500 Ω/ | % T @ 500 Ω/ |
|---|---|---|
| Ratio of TSA:CNT | □as sprayed | □after rinse |
| 0.5 | 87.3 | 89.3 |
| 1 | 91.1 | 93.4 |
| 2 | 89.4 | 91.7 |
| 5 | 81.7 | 91.3 |
| 10 | 67.2 | 90.8 |

### Example 11

### Cellulose (HPMC) Added to CNT Ink

HPMC was added to ink in a similar fashion to that described above. In these experiments, the HPMC was added in higher concentrations to determine how much loading was considered to be detrimental. As can be seen from Table 3, HPMC is detrimental to RT performance at much lower loading than Nafion. The inks remained stable with the addition of HPMC.

### Polyvinylpyrrolidone (PVP) Added to CNT Ink

PVP was added to ink in a similar fashion to that described above. In these experiments, the PVP was added in higher concentrations to determine how much loading was considered to be detrimental. As can be seen from Table 3, PVP is detrimental to RT performance at much lower loading than Nafion. The inks remained stable with the addition of PVP.

TABLE 3
Ratio of SWnT to HPMC and PVP Polymer vs. sheet resistance
and transparency

| | RATIO SWNT to | | | % T @ 500 |
|---|---|---|---|---|
| Polymer | POLYMER in ink | Ohms/Square | % T | Ohms/Square |
| HPMC | 5 to 1 | 2305 | 81.7 | 56.4 |
| HPMC | 2.5 to 1 | 515 | 70 | 69.5 |
| HPMC | 1 to 1 | 504 | 78.2 | 77.3 |
| HPMC | 1 to 1.25 | 497.5 | 80.7 | 80.7 |
| HPMC | 1 to 5 | 454.5 | 81.3 | 82.4 |
| Control | Control | 468 | 85.6 | 86.1 |
| PVP | 5 to 1 | 14450 | 84.9 | 19.8 |
| PVP | 2.5 to 1 | 1740 | 81.2 | 61.5 |
| PVP | 1 to 1 | 1221.5 | 83.4 | 71.6 |
| PVP | 1 to 1.25 | 700.5 | 84.1 | 80.4 |
| PVP | 1 to 5 | 512 | 81.7 | 81.4 |
| Control | Control | 415.5 | 79.3 | 81.8 |

### Example 12 PVA, PSS, and PSS/PVA Binders for UV Protection

PVA and PSS binders were dip coated onto CNT films on glass slides. Resistance was measured using painted silver electrodes, and the results can be seen in Table 4.

TABLE 4
PVA, PSS and PSS/PVA binders and resistance upon UV exposure

| | | | Ohms/Square 17 |
|---|---|---|---|
| Binder | | Ohms/Square | hours of UV |
| coating | Ohms/Square Start | After coating | exposure |
| PVA only 1% | 336 | 445.5 | 782 |
| PSS only | 427 | 385.5 | 447 |
| PSS and | 482 | 544.5 | 1117 |
| PVA | | | |
| No binder | 470.5 | 460 | 635 |

### Example 13 Removal of Metal Impurities

Single walled carbon nanotubes were purified into a paste. The paste was dried in air at 100 degrees C. for 2 hours. The sample weight was measured to be L711 mg after drying. The sample was heated at 2 degrees C. per minute to 1,000 degrees C. The sample was held to 1000 degrees C. for 500 hours to convert remaining metals to metal oxides. The purified sample shows 5.000% ash weight. The catalyst used was iron, meaning the residual weight is iron oxide, Fe2O3. Thus, 5.000% ash×69.94% Fe in Fe2O3=3.497% iron in the initial sample. The maximum burn rate at 509 degrees C. in air is a sign of high graphitization of the nanotubes and removal of metal catalyst, which lowers the oxidation temperature of CNTs. It should be noted that long-term instrument stability is between 20-40 micrograms. A 5 milligram sample with approximately an error of +−2.3% in the ash weight. See FIG. 11.

### Example 14

Double walled carbon nanotubes were purified into a paste. The paste was dried in air at 100 degrees C. for 2 hours. The sample weight was measured to be 4.934 mg after drying. The sample was heated at 2 degrees C. per minute to 1,000 degrees C. The sample was held to 1,000 degrees C. for 500 hours to convert remaining metals to metal oxides. The purified sample shows 2.713% ash weight. The catalyst used was iron, meaning the residual weight is iron oxide, Fe2O3. Thus, 2.713% ash×69.94% Fe in Fe2O3=1.897% metal in the initial sample. The maximum burn rate at 540 degrees C. in air is a sign of high graphitization of the nanotubes and removal of metal catalyst, which lowers the oxidation temperature of CNTs. It should be noted that long-term instrument stability is between 20-40 micrograms. A 4.934 milligram sample with approximately an error of +−0.8% in the ash weight. See FIG. 12.

### Example 15

Near infrared spectroscopy has been used to measure nanotube purity, with findings of “100% single walled carbon nanotubes” having S22 transition area to total area of 0.141. Less pure samples have a smaller ratio because nanotube transitions are weaker, and the plasmon background from carbon impurities is greater. The spectrum of a nanotube film was measured from 2,500 nm to 400 nm. Integrating the S22 peak area to plasmon area according to Itkis et al, a ratio of 0.202 for was found for the samples used, which would indicate a nanotube purity of 143%. Itkis et al.'s ratio is 0.141 because it the best that they could purify a sample using state of the art techniques. This experiment achieved purities in excess of that seen by Itkis et al. with arc discharge carbon nanotubes. These results may be attributed at least in part to the purity in the instant invention achieved by the elimination of carbonaceous non-nanotube impurities. A metal content less than 2% in TGA and less than 1% was seen in film techniques. See FIGS. 13 and 14.

Other embodiments and uses of the invention will be apparent to those skilled in the art from consideration of the specification and practice of the invention disclosed herein. All references cited herein, including all publications, U.S. and foreign patents and patent applications, are specifically and entirely incorporated by reference. It is intended that the specification and examples be considered exemplary only with the true scope and spirit of the invention indicated by the following claims.

### REFERENCES

1. J. Am Chem. Soc. 2005, 127, 17548-17555

Electroanalysis 2004, 16, no. 1-2

3. Michot, U.S. Pat. No. 6,171,522

4. Chittibabu, U.S. Pat. No. 6,900,382

5. Mikoshiba, U.S. Pat. No. 6,384,321

6. Kang, U.S. Pat. No. 6,756,537

7. Luo, US Patent Application 20050209392

8. Glatkowski, US Patent Application 20030122111

9. Glatkowski, US Patent Application 20040265550

### 10. Martin, US Patent Application 20030179986

### 11. Itkis et al., Journal of the American Chemical Society, 127, 3439-3448 (2005)

12. Evans Analytical Group Quick Reference Table, available of http://www.englabs.com/en-US/services/EvanWallChart_{—}1219×1.pdf.

1. A method of forming a stable transparent conductive coating comprising purifying the carbon nanotubes so that they contain no detectable metals, forming a layer of carbon nanotubes, and adding one or more binders in a second coating step.

2. The method of claim 1, wherein the binder further comprises a solvent.

3. The method of claim 2, wherein the solvent is removed.

4. The method of claim 1, wherein the coating imparts stable electronic properties and optical properties to the coating when said coating is exposed to environmental conditions.

5. The method of claim 4, wherein electronic properties comprise surface resistance, and wherein said surface resistance changes less than 100%, less than 90%, less than 80%, less than 70%, less than 60%, less than 50%, less than 40%, less than 30%, less than 20%, less than 10%, less than 5%, or less than 1%, upon exposure to the environmental conditions.

6. The method of claim 4, wherein the environmental conditions include temperatures ranging from 20 to 200 degrees Celsius for periods of time ranging from 1 hour to 5 years.

7. The method of claim 4, wherein the environmental conditions include humid condition wherein relative humidity ranges from 10-100%.

8. The method of claim 4, wherein the environmental conditions include UV radiation ranging from 280 nm to 400 nm.

9. The method of claim 4, wherein the environmental conditions comprise UVA radiation or UVB radiation.

10. A method of forming a thin transparent and conductive thin coating comprising depositing a first layer of carbon nanotubes on a substrate, adding a solvent containing binder to the first layer with the solvent containing binder to form a composite wherein the ratio of the carbon nanotubes to the binder is greater than 10% weight, greater than 50% by weight, or greater than 90% by weight.

11. The method of claim 1, wherein the coating is homogeneous in the X direction, the Y direction, the Z direction, or combinations thereof.

12. A method of forming a thin transparent and conductive coating comprising depositing carbon nanotubes blended with a binder in a solution, wherein the ratio of the carbon nanotubes to the binder is greater than 10% by weight, greater than 50% by weight, or greater than 90% by weight.

13. A method for increasing the transparency of a carbon nanotube coating by between 1% and 10% comprising adding one or more binders to the carbon nanotube coating.

14. The method of claim 13, wherein the transparency value of the coating is proportional to the transparency of the substrate.

15. A transparent and conductive composition comprised of carbon nanotubes, wherein the composition contains no detectable metal.

16. The composition of claim 15, wherein the detectable metal is selected from the group consisting of Iron, Itrium, Nickel, Cobalt, Mo, and combinations thereof.

17. The composition of claim 15, further comprising a binder.

18. The composition of claim 17, wherein the binder is selected from the group consisting of a dopant, nafion, flemion, thionyl chloride, TCNQ, oxygen, water, nitric acid, sulfurinc acid, a polymeric acid, a fluoropolymeric acid, polystyrene sulfonic acid, phosphoric acid, polyphosphoric acid, polyacrylic acid, a polymer, an acid, a superacid, a metal oxide, a salt and combinations thereof.

19. The composition of claim 15, wherein the carbon nanotubes form a homogenous layer with a thickness of less than 50 nm, 40 nm, less than 30 nm, less than 20 nm, or less than 10 nm.

20. The composition of claim 15, wherein the composition has a sheet resistance of less than 10⁴ Ω/□, less than 10³ Ω/□, less than 10² Ω/□, or less than 10 Ω/□.

21. The composition of claim 15, wherein the composition has a carbon purity of more than 90%, more than 95%, more than 98%, or more than 99%.

22. The composition of claim 15, wherein the composition contains less than 5% metal, less than 3% metal, less than 2% metal, less than 1% metal, or less than 0.1% metal.

23. The composition of claim 15. wherein the composition has stable electronic properties as measured by LTD upon exposure to environmental conditions.

24. The composition of claim 23, wherein the electronic properties change less than 50%, less than 40%, less than 30%, less than 20%, less than 10%, less than 5%, or less than 1%.

25. The composition of claim 23, wherein the environmental conditions are extreme temperatures, humidity, or UV radiation.

26. The composition of claim 15, wherein the composition has a stable optical property upon exposure to environmental conditions.

27. The composition of claim 26, wherein the stable optical property is selected from the group consisting of diffuse transparency, specular transparency, haze, diffuse reflectance, specular reflectance, and absorbance.

28. The composition of claim 26, wherein the stable optical property changes less than 50%, less than 40%, less than 30%, less than 20%, less than 10%, less than 5%, or less than 1%.

29. The composition of claim 26, wherein the environmental conditions are extreme temperatures, humidity, or UV radiation.
